(19) United States
(12) Patent Application Publication
(10) Pub. No.: US 2021/0111228 A1
(43) Pub. Date: Apr. 15, 2021

(54) DISPLAY DEVICE, METHOD FOR MANUFACTURING DISPLAY DEVICE, AND ELECTRONIC APPARATUS

(71) Applicant: Sony Semiconductor Solutions Corporation, Kanagawa (JP)

(72) Inventor: Tomoyoshi Ichikawa, Kanagawa (JP)

(21) Appl. No.: 17/044,039

(22) PCT Filed: May 7, 2019
(86) PCT No.: PCT/JP2019/018217

§ 371 Date: Sep. 30, 2020

(30) Foreign Application Priority Data
May 15, 2018 (JP) 2018-093780

(51) Int. Cl. H01L 27/32; H01L 51/52; H01L 51/56

(52) U.S. Cl. CPC H01L 27/3206; H01L 51/5234; H01L 51/5218; H01L 51/56; H01L 51/5265

(57) ABSTRACT

In a display device, a reflection film and a semi-transmissive reflection film are disposed at a distance from each other, the distance differing depending on an emission color of a pixel, an organic layer and a cathode electrode being transparent are stacked between the reflection film and the semi-transmissive reflection film, the organic layer including a light emission layer, the semi-transmissive reflection film is formed on the cathode electrode, and the cathode electrode is formed to have a film thickness that differs depending on the emission color.

### TECHNICAL FIELD

The present disclosure relates to a display device, a method for manufacturing a display device, and an electronic apparatus.

### BACKGROUND ART

In recent years, an organic electroluminescence (EL) display device employing EL based on an organic material has been attracting attention as an alternative display device to liquid crystal display devices. In addition, organic EL display devices are being applied not only to direct-view displays such as monitors but also to micro-displays in which a pixel pitch as fine as several microns is required.

One method for achieving color display on an organic EL display device includes forming organic EL material layers, for each pixel, using a mask for light emission of a plurality of colors including, for example, red light emission, green light emission, and blue light emission. Furthermore, in addition to the aforementioned method, there is a method that includes forming an organic EL material layer for white light emission for all the pixels in common and disposing a color filter for each pixel. This method has an advantage that alignment is not required for forming the organic EL material layer. However, the method involving combination of an organic EL material layer for white light emission with a color filter suffers from reduced luminous efficacy because the white light is color-separated by the color filter. For this reason, there is known a technology for achieving improvement in luminous efficacy and color reproducibility by forming a resonator structure for enhancing the light having a particular wavelength by a resonance effect.

To enhance the light having a particular wavelength by the resonance effect, it is necessary to adjust the optical distance between the reflection film and the semi-transmissive reflection film in accordance with the wavelength. Patent Document 1 discloses a technology in which an optical path length adjustment layer is provided above a transparent electrode serving as an upper electrode, and a semi-transmissive reflection film is formed on the optical path length adjustment layer.

### CITATION LIST

### Patent Document

### Patent Document 1: Japanese Patent Application Laid-Open No. 2009-272150

### SUMMARY OF THE INVENTION

### Problems to be Solved by the Invention

In general, a configuration in which an optical path length adjustment layer is provided above a transparent electrode serving as an upper electrode and a semi-transmissive reflection film is formed on the optical path length adjustment layer requires the optical path length adjustment layer to be formed into an extremely thin layer. Accordingly, it is difficult to control the film thickness with high precision, causing a problem of difficulty in manufacture.

Therefore, an object of the present disclosure is to provide a display device having a structure in which an optical distance in a resonator structure can be set with high precision without using an optical path length adjustment layer, an electronic apparatus equipped with the display device, and a method for manufacturing the display device.

### Solutions to Problems

For achieving the above-described object, a display device according to the present disclosure is

a display device, in which

a reflection film and a semi-transmissive reflection film are disposed at a distance from each other, the distance differing depending on an emission color of a pixel,

an organic layer and a cathode electrode being transparent are stacked between the reflection film and the semi-transmissive reflection film, the organic layer including a light emission layer,

the semi-transmissive reflection film is formed on the cathode electrode, and

the cathode electrode is formed to have a film thickness that differs depending on the emission color.

For achieving the above-described object, a method for manufacturing a display device according to the present disclosure is

a method for manufacturing a display device, in which a reflection film and a semi-transmissive reflection film are disposed at a distance from each other, the distance differing depending on an emission color of a pixel, an organic layer and a cathode electrode being transparent are stacked between the reflection film and the semi-transmissive reflection film, the organic layer including a light emission layer, the semi-transmissive reflection film is formed on the cathode electrode, and the cathode electrode is formed to have a film thickness that differs depending on the emission color, the method including steps of:

forming the cathode electrode on an entire surface including the organic layer; and

making the cathode electrode in such a way as to have a film thickness that differs depending on the emission color.

For achieving the above-described object, an electronic apparatus according to the present disclosure is

an electronic apparatus including a display device, in which

a reflection film and a semi-transmissive reflection film are disposed at a distance from each other, the distance differing depending on an emission color of a pixel,

an organic layer and a cathode electrode being transparent are stacked between the reflection film and the semi-transmissive reflection film, the organic layer including a light emission layer,

the semi-transmissive reflection film is formed on the cathode electrode, and

the cathode electrode is formed to have a film thickness that differs depending on the emission color.

### BRIEF DESCRIPTION OF DRAWINGS

FIG. 1 is a schematic plan view of a display device according to a first embodiment of the present disclosure.

FIG. 2 is a schematic partial cross-sectional view of the display device according to the first embodiment.

FIGS. 3A and 3B are schematic partial end views for explaining a method for manufacturing the display device according to the first embodiment.

FIG. 4 is a schematic partial end view for explaining the method for manufacturing the display device according to the first embodiment, as continued from FIG. 3B.

FIG. 5 is a schematic partial end view for explaining the method for manufacturing the display device according to the first embodiment, as continued from FIG. 4.

FIG. 6 is a schematic partial end view for explaining the method for manufacturing the display device according to the first embodiment, as continued from FIG. 5.

FIG. 7 is a schematic partial end view for explaining the method for manufacturing the display device according to the first embodiment, as continued from FIG. 6.

FIG. 8 is a schematic partial end view for explaining the method for manufacturing the display device according to the first embodiment, as continued from FIG. 7.

FIG. 9 is a schematic partial end view for explaining the method for manufacturing the display device according to the first embodiment, as continued from FIG. 8.

FIG. 10 is a schematic partial cross-sectional view of a display device according to a second embodiment.

FIG. 11 is a schematic partial end view for explaining a method for manufacturing the display device according to the second embodiment, as continued from FIG. 10.

FIG. 12 is a schematic partial end view for explaining the method for manufacturing the display device according to the second embodiment, as continued from FIG. 11.

FIG. 13 is a schematic partial cross-sectional view of a display device according to a third embodiment.

FIG. 14 is a schematic partial cross-sectional view of a display device according to a fourth embodiment.

FIG. 15 is a schematic partial cross-sectional view of the display device according to the fourth embodiment.

FIG. 16 is a schematic partial end view for explaining a method for manufacturing the display device according to the second embodiment, as continued from FIG. 15.

FIG. 17 is an external view of a lens-interchangeable single-lens reflex type digital still camera; FIG. 17A shows a front view thereof and FIG. 17B shows a rear view thereof.

FIG. 18 is an external view of a head-mounted display.

FIG. 19 is an external view of a see-through head-mounted display.

### MODE FOR CARRYING OUT THE INVENTION

With reference to the drawings, the present disclosure will now be described on the basis of embodiments. The present disclosure is not limited to the embodiments, and various numerical values and materials in the embodiments are examples. In the following description, the same elements or elements having the same functions will be denoted by the same reference symbols, and redundant descriptions will be omitted. Note that descriptions will be provided in the order mentioned below.

1. General description of a display device, a method for manufacturing a display device, and an electronic apparatus of the present disclosure

2. First Embodiment

3. Second Embodiment

4. Third Embodiment

5. Fourth Embodiment

6. Description of electronic apparatus and others

### [General Description of a Display Device, a Method for Manufacturing a Display Device, and an Electronic Apparatus of the Present Disclosure]

A display device according to the present disclosure, a display device used for an electronic apparatus according to the present disclosure, and a display device obtained by a method for manufacturing the display device according to the present disclosure (hereinafter may be simply referred to as a “display device of the present disclosure”) may have a configuration in which a reflection film has a function of an anode electrode.

The reflection film can be formed by using light reflecting material such as aluminum (Al), an aluminum alloy, platinum (Pt), gold (Au), chromium (Cr), tungsten (W), and the like. The thickness of the reflection film is preferably set to a range of, for example, 100 to 300 nanometers.

Note that in a case where the reflection film and the anode electrode are separately formed, the anode electrode can be formed by using a transparent conductive material such as indium tin oxide (ITO) or indium zinc oxide (IZO). In this case, the anode electrode is only needed to be disposed between the reflection film and the organic layer.

In the display device of the present disclosure including various preferred configurations described above, the cathode electrode can be formed by using a transparent conductive material such as indium tin oxide (ITO), indium zinc oxide (IZO), or the like. Preferably, the cathode electrode is formed by using indium zinc oxide (IZO), among others. The cathode electrode can be formed by a film forming method such as a sputtering method, for example.

The film forming temperature for indium zinc oxide (IZO) is lower than the film forming temperature for indium tin oxide (ITO). Since a film of the cathode electrode is formed on the organic layer, in consideration of the influence on the organic layer, it is preferable to select indium zinc oxide (IZO), which allows the cathode electrode to be film-formed at a lower temperature.

In the display device of the present disclosure including various preferred configurations described above, the cathode electrode is formed into an electrode common to the individual pixels, and a recess may be disposed in a portion of the cathode electrode corresponding to the reflection film. In this case, the depth of the recess may differ depending on the emission color. Furthermore, a method for manufacturing the display device according to the present disclosure may include making the cathode electrode in such a way as to have a film thickness that differs depending on the emission color by forming a recess in a portion of the cathode electrode corresponding to the reflection film. In this case, it is preferable to make the cathode electrode using a dry etching technology.

In the display device of the present disclosure including various preferred configurations described above, the cathode electrode may be formed to have a film thickness that differs depending on the emission color, whereby the optical distance between the reflection film and the semi-transmissive reflection film can be set in accordance with the display color of the pixel. In this case, the optical distance L may be needed to satisfy the following condition:

2L/λ+Φ/2π=m (m is an integer)

where the symbol Φ represents the phase shift of reflected light generated in the semi-transmissive reflection film and the reflection film, the symbol L represents the optical distance between the reflection film and the semi-transmissive reflection film, and the symbol λ represents the peak wavelength of a spectrum of light taken from a pixel.

In the display device of the present disclosure including various preferred configurations described above, the semi-transmissive reflection film can be formed by using a metal material having good light transmittance and light reflectivity, and examples thereof may include metals such as silver (Ag), gold (Au), copper (Cu), aluminum (Al), and magnesium (Mg), and alloys thereof. From the viewpoint of light transmittance and light reflectivity, the semi-transmissive reflection film preferably includes silver or an alloy including silver. The thickness of the semi-transmissive reflection film is preferably set to a range of, for example, 5 to 40 nanometers.

In the display device of the present disclosure including various preferred configurations described above, the light emission layer may be formed in common throughout the individual pixels. In this case, the light emission layer may be configured to emit white light.

In this configuration, the organic layer is disposed as a common continuous film on the entire surface including the reflection film. The organic layer emits light when a voltage is applied. The organic layer may have a structure in which, for example, a hole injection layer, a hole transport layer, a light emission layer, an electron transport layer, and an electron injection layer are stacked in the order mentioned from the reflection film side. A hole transport material, a hole transport material, an electron transport material, and an organic light emission material included in the organic layer are not particularly limited and a well-known material can be used.

The organic layer may have a so-called tandem structure in which a plurality of light emission layers is connected via a charge generation layer or an intermediate electrode. For example, a light emission layer that emits white light can be formed by stacking light emission layers that emit red light, green light, and blue light, or by stacking light emission layers that emit yellow light and blue light.

Alternatively, the light emission layer may be formed for each pixel. In this case, the light emission layer may be configured to emit light of a color corresponding to the emission color of the pixel. In this case, individual layers included in the organic layer except the light emission layer may still be disposed as a common continuous film over the entire surface including the reflection film.

In the case of a color display configuration, a single pixel may include a plurality of sub-pixels. Specifically, a single pixel may include three sub-pixels: a red display sub-pixel, a green display sub-pixel, and a blue display sub-pixel. Moreover, a single pixel may include a set of sub-pixels in which one or more types of sub-pixels are added to these three types of sub-pixels (for example, a set in which a sub-pixel that emits white light for higher brightness is added, a set in which a sub-pixel that emits complementary color light for expanding a color reproduction range is added, a set in which a sub-pixel that emits yellow light for expanding a color reproduction range is added, or a set in which sub-pixels that emit yellow light and cyan light for expanding a color reproduction range are added).

Examples of pixel values of the display device may include, without limitation, some resolutions for image display such as VGA (640, 480), S-VGA (800, 600), XGA (1024, 768), APRC (1152, 900), S-XGA (1280, 1024), U-XGA (1600, 1200), HD-TV (1920, 1080), Q-XGA (2048, 1536), as well as (1920, 1035), (720, 480), (1280, 960), and the like.

An insulation film and others used in the display device can be formed by using a material appropriately selected from known inorganic materials and organic materials, and can be formed by, for example, a well-known film forming method such as a physical vapor deposition method (PVD method) exemplified by a vacuum evaporation method and a sputtering method, various chemical vapor deposition methods (CVD methods), and the like. Furthermore, the patterning may be performed by a combination of well-known patterning methods such as an etching method and a lift-off method.

In the display device according to the present disclosure, the configuration of the drive circuit or the like that controls light emission from the light emission unit is not particularly limited. The light emission unit may be formed on a certain plane over the circuit board and, for example, disposed via the interlayer insulation layer above the drive circuit that drives the light emission unit. The configuration of the transistor included in the drive circuit is not particularly limited. The transistor may be a p-channel type field effect transistor or an n-channel type field effect transistor.

Examples of a material included in the circuit board may include a semiconductor material, a glass material, or a plastic material. In a case where the drive circuit includes a transistor formed on a semiconductor substrate, for example, a well region is only needed to be disposed on the semiconductor substrate including silicon and the transistor is only needed to be formed in the well. On the other hand, in a case where the drive circuit includes a thin film transistor or the like, the drive circuit can be formed by forming a semiconductor thin film on a substrate that includes a glass material or a plastic material. Various types of wiring may have a well-known configuration and structure.

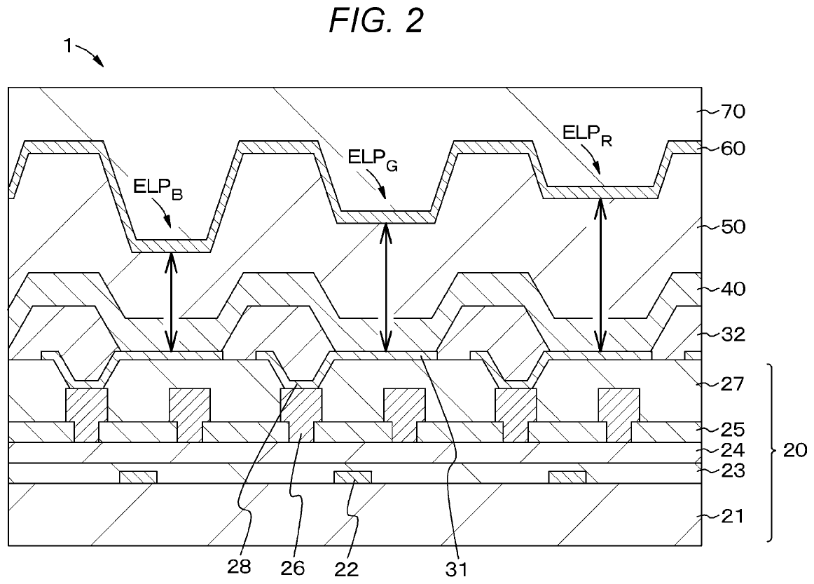

A condition shown in each of a variety of formulas herein is satisfied not only in a case where the formula is mathematically precisely satisfied but also in a case where the formula is substantially satisfied. For a formula to be satisfied, various variations occurring in the design or manufacture of the display element, the display panel, or the like are permitted to be present. Furthermore, the drawings referred to in the following description are schematic drawings. For example, FIG. 2 described later shows a cross-sectional structure of the display device, but does not indicate ratios of width, height, thickness, and the like.

### First Embodiment

The first embodiment relates to a display device, a method for manufacturing a display device, and an electronic apparatus according to a first aspect of the present disclosure.

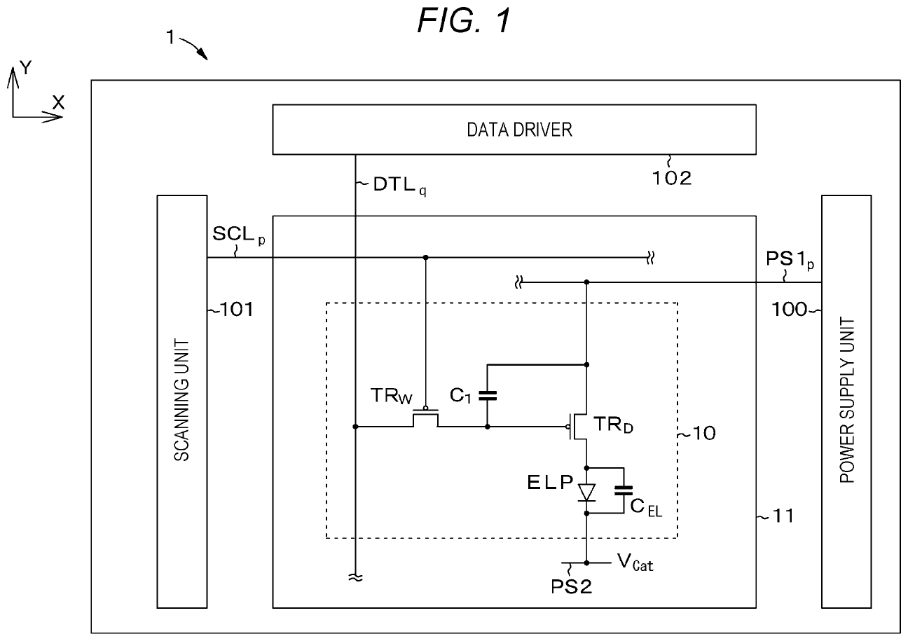

FIG. 1 is a schematic plan view of a display device according to a first embodiment of the present disclosure. The display device 1 includes a display region 11 in which pixels 10 each including a light emission unit ELP and a drive circuit that drives the light emission unit ELP are arranged in a two-dimensional matrix while being connected to a scanning line SCL extending along the row direction (X direction in FIG. 1) and to a data line DTL extending along the column direction (Y direction in FIG. 1), and also includes a power supply unit 100 that supplies voltages to a power supply line PS1, a scanning unit 101 that supplies scanning signals to the scanning line SCL, and a data driver 102 that supplies signal voltages to the data line DTL. Note that FIG. 1 shows a single pixel 10 for convenience of illustration, or more specifically, FIG. 1 shows a connection relationship in the (q, p)-th pixel 10 as described later.

The display device 1 further includes a common power supply line PS2 that is connected to all the pixels 10 in common. A predetermined drive voltage is supplied from the power supply unit 100 to the power supply line PS1, while a common voltage (a ground potential, for example) is supplied to the common power supply line PS2.

Although not illustrated in FIG. 1, the display region 11 includes a total of Q×P pixels (display elements) 10, namely Q pixels along the row direction and P pixels along the column direction, arranged in a two-dimensional matrix. In the display region, the number of rows of the pixels 10 is P and the number of pixels 10 constituting each row is Q.

Furthermore, the number of the scanning lines SCL and the number of power supply lines PS1 are each P. The pixels 10 in the p-th row (where p=1, 2, . . . , P) are connected to the p-th scanning line SCLₚ and the p-th power supply line PS1ₚ to constitute a single display element row. Note that FIG. 1 shows the scanning line SCLₚ and the power supply line PS1ₚ only.

Furthermore, the number of the data lines DTL is Q. The pixels 10 in the q-th column (where q=1, 2, . . . , Q) are connected to the q-th data line DTL_{q}. Note that FIG. 1 shows the data line DTL_{q} only.

The display device 1 is, for example, a color display device. A single pixel 10 constitutes a single sub-pixel. The display device 1 is line-sequentially scanned row by row in response to a scanning signal from the scanning unit 101. The pixel 10 located in the p-th row and the q-th column is hereinafter referred to as a (q, p)-th pixel 10 or the (q, p)-th pixel 10.

In the display device 1, Q pixels 10 arranged in the p-th row are simultaneously driven. In other words, in the Q pixels 10 arranged along the row direction, the timing of light emission/non-emission is controlled for each row to which the pixels belong. Assuming that the display frame rate of the display device 1 is denoted by FR (times/second), the scanning period (so-called horizontal scanning period) per row when the display device 1 is line-sequentially scanned row by row is less than (1/FR)×(1/P) seconds.

The pixel 10 includes the light emission unit ELP and the drive circuit that drives the light emission unit ELP. The light emission unit ELP includes an organic electroluminescent light emission unit. The drive circuit includes a write transistor TR_{W}, a drive transistor TR_{D}, and a capacitance unit C₁. When a current flows through the light emission unit ELP via the drive transistor TR_{D}, the light emission unit ELP emits light. Each transistor includes a p-channel type field effect transistor.

In the pixel 10, one source/drain region of the drive transistor TR_{D} is connected to one end of the capacitance unit C₁ and to the power supply line PS1, while the other source/drain region is connected to one end (specifically, the anode electrode) of the light emission unit ELP. The gate electrode of the drive transistor TR_{D} is connected to the other source/drain region of the write transistor TR_{W} and is also connected to the other end of the capacitance unit C₁.

Furthermore, in the write transistor TR_{W}, one source/drain region is connected to the data line DTL and the gate electrode is connected to the scanning line SCL.

The other end (specifically, the cathode electrode) of the light emission unit ELP is connected to the common power supply line PS2. A predetermined cathode voltage V_{cat} is supplied to the common power supply line PS2. Note that the capacitance of the light emission unit ELP is denoted by the symbol C_{EL}.

The following describes driving of the pixel 10 in outline. When the write transistor TR_{W} is caused to become conductive by a scanning signal from the scanning unit 101 while a voltage corresponding to the brightness of the image to be displayed is supplied from the data driver 102 to the data line DTL, the voltage corresponding to the brightness of the image to be displayed is written to the capacitance unit C₁. After the write transistor TR_{W} is caused to become non-conductive, a current flows through the drive transistor TR_{D} in accordance with the voltage held in the capacitance unit C₁, whereby the light emission unit ELP emits light.

Note that, in the present disclosure, the configuration of the drive circuit that controls light emission of the pixel 10 is not particularly limited. Therefore, the configuration illustrated in FIG. 1 is merely an example, and the display device according to the present embodiment may have various configurations.

The following describes a detailed structure of the display device 1.

FIG. 2 is a schematic partial cross-sectional view of the display device according to the first embodiment.

In the display device 1, a reflection film 31 has a function of an anode electrode. The reflection film 31 may be hereinafter referred to as a reflection film (anode electrode) 31. The reflection film 31 and a semi-transmissive reflection film 60 are placed to have a distance therebetween that differs depending on the emission color of the pixel 10. An organic layer 40 where a light emission layer is included and a transparent cathode electrode 50 are stacked between the reflection film 31 and the semi-transmissive reflection film 60. The semi-transmissive reflection film 60 is formed on the cathode electrode 50, and the cathode electrode 50 is formed to have a film thickness that differs depending on the emission color.

The light emission unit ELP includes the reflection film 31, the organic layer 40, and the cathode electrode 50, which are stacked together. Note that the light emission unit that emits red light is denoted by the symbol ELP_{R}, the light emission unit that emits green light is denoted by the symbol ELP_{G}, and the light emission unit that emits blue light is denoted by the symbol ELP_{B}.

The reflection film (anode electrode) 31 is disposed for each light emission units ELP, and a partition 32 serving as an inter-pixel insulation film is formed between adjacent reflection films 31. In addition, the organic layer 40 and the cathode electrode 50 are stacked over the entire surface including the reflection film 31 and the partition 32. Moreover, the semi-transmissive reflection film 60 is disposed on the cathode electrode 50, and a protection film 70 is placed on the semi-transmissive reflection film 60.

The reflection film 31 is formed on an interlayer insulation film 27. A resonator structure is formed between the light reflecting surface of the reflection film 31 and the semi-transmissive reflection film 60 (the portion indicated by an arrow in the figure).

The cathode electrode 50 is formed to be an electrode common to the individual pixels 10. In addition, a recess is disposed in a portion of the cathode electrode 50, the portion corresponding to the reflection film (anode electrode) 31. The depth of the recess differs depending on the emission color.

By providing these recesses, the cathode electrode 50 is formed to have a film thickness that differs depending on the emission color, whereby the optical distance between the reflection film 31 and the semi-transmissive reflection film 60 is set in accordance with the display color of the pixel 10. The optical distance L is set so as to satisfy the following condition:

2L/λ+Φ/2π=m (m is an integer)

where the symbol Φ represents the phase shift of reflected light generated in the reflection film 31 and the semi-transmissive reflection film 60, the symbol L represents the optical distance between the reflection film 31 and the semi-transmissive reflection film 60, and the symbol λ represents the peak wavelength of a spectrum of light taken from the pixel 10.

Various components will now be described in detail with reference to FIG. 2.

The circuit board 20 includes: a base material 21; a gate electrode 22 formed on the base material 21; a gate insulation film 23 formed to cover the entire surface of the gate electrode 22; a semiconductor material layer 24; an interlayer insulation film 25 formed to cover the entire surface including the semiconductor material layer 24; a source/drain electrode 26 connected to a source/drain region of a transistor formed in the semiconductor material layer 24; and a planarization film 27 formed to cover the entire surface including the source/drain electrode 26.

The circuit board 20 is equipped with a drive circuit including the transistor and others described above for driving the pixel 10. In addition, the reflection film (anode electrode) 31 and the drive circuit are electrically connected. More specifically, the reflection film (anode electrode) 31 is connected to the source/drain electrode 26 of the transistor formed in the semiconductor material layer 24 via the contact plug 28. The contact plug 28 includes a metal material such as, for example, copper (Cu) or a copper alloy, and is formed in an opening provided in the planarization film 27.

The base material 21 may include, for example, a glass material, a semiconductor material, a plastic material, or the like. The drive circuit including a thin film transistor that controls light emission of the light emission unit ELP is formed on the base material 21.

The gate electrode 22 for various transistors included in the drive circuit may be formed by using, for example, aluminum (Al) or some other metal, polysilicon, or the like. The gate insulation film 23 is disposed on the entire surface of the base material 21 so as to cover the gate electrode 22. The gate insulation film 23 can be formed by using, for example, silicon oxide (SiGₓ), silicon nitride (SiNₓ), or the like.

The semiconductor material layer 24 can be formed on the gate insulation film 23 by using, for example, amorphous silicon, polycrystalline silicon, an oxide semiconductor, or the like. Furthermore, some regions of the semiconductor material layer 24 are doped with an impurity to form a source/drain region. Moreover, the semiconductor material layer 24 includes a region that is located between one source/drain region and the other source/drain region and above the gate electrode 22 to form a channel region. With these components, a bottom-gate type thin film transistor is disposed on the base material 21. Note that illustration of the source/drain regions and the channel region is omitted in FIG. 2.

The interlayer insulation film 25 is disposed on the semiconductor material layer 24. The interlayer insulation film 25 includes, for example, silicon oxide (SiOₓ), silicon nitride (SiNₓ), silicon oxynitride (SiOₓN_{y}), or the like. The source/drain electrode 26 is connected to the semiconductor material layer 24 via a contact hole provided in the interlayer insulation film 25. The source/drain electrode 26 includes a metal such as, for example, aluminum (Al).

The planarization film 27 is formed for the purpose of covering and planarizing the drive circuit and others. The planarization film 27 can be formed by using, for example, an organic insulation film such as a polyimide-based resin, an acrylic-based resin, or a novolak-based resin, or an inorganic insulation film such as silicon oxide (SiOₓ), silicon nitride (SiNₓ), or silicon oxynitride (SiOₓN_{y}).

The contact plug 28 includes a metal material such as, for example, copper (Cu) or a copper alloy, and is formed in an opening provided in the planarization film 27. The reflection film (anode electrode) 31 and the source/drain electrode 26 of the drive transistor are electrically connected by the contact plug 28.

The reflection film 31 is formed on the planarization film 27. The reflection film 31 includes a light reflecting material such as aluminum (Al). The thickness of the reflection film is preferably set to a range of, for example, 100 to 300 nanometers. Note that, in some cases, the reflection film may be formed by stacking a transparent conductive material and the light reflecting material described above.

The organic layer 40 is formed on the entire surface including the reflection film 31 and the partition 32. The light emission layer in the organic layer 40 is formed in common throughout the individual pixels 10 and emits white light.

Specifically, the organic layer 40 may have a structure in which a hole injection layer, a hole transport layer, a red light emission layer, a light emission separation layer, a blue light emission layer, a green light emission layer, and an electron transport layer, which include an organic material, are sequentially stacked. Alternatively, the organic layer 40 may have a structure in which a hole injection layer, a hole transport layer, a blue light emission layer, an electron transport layer, a charge generation layer, a hole injection layer, a hole transport layer, a yellow light emission layer, and an electron transport layer are sequentially stacked from the bottom layer. Note that the organic layer 40 has a multilayer structure, but is illustrated as a single layer in the figure.

The transparent cathode electrode 50 is formed on the entire surface including the organic layer 40. The cathode electrode 50 includes a material that has high light transmissibility and a low work function. The description is provided here on the assumption that the cathode electrode includes indium zinc oxide (IZO). The thickness of the cathode electrode is set such that the film thickness satisfies the resonance condition corresponding to the pixel color, and may be set to a range of 10 to 200 nanometers, for example.

The semi-transmissive reflection film 60 is intended to enhance the microcavity effect, and is formed on the cathode electrode 50. The description is provided here on the assumption that the semi-transmissive reflection film 60 includes silver or an alloy including silver. The thickness of the semi-transmissive reflection film 60 is preferably set to a range of, for example, 5 to 40 nanometers.

The protection film 70 is formed on the entire surface including the semi-transmissive reflection film 60. The protection film 70, which is intended to prevent moisture from entering the organic layer 40, includes a material having low water permeability and is formed to have a thickness of about 1 to 8 micrometers. As a material of the protection film 70, silicon nitride (SiNₓ), silicon oxide (SiOₓ), aluminum oxide (AlOₓ), titanium oxide (TiOₓ), or a combination thereof is used.

Note that a counter substrate on which a color filter or the like is formed may be further disposed on the protection film 70. The counter substrate can be disposed by sticking the counter substrate on the protection film 70 with an ultraviolet curable resin, a thermosetting resin, or the like.

The foregoing has described a detailed structure of the display device 1. The above-described display device 1 can be manufactured as follows.

The following describes a method for manufacturing the display device 1 described above. The method for manufacturing the display device 1 includes the steps of:

forming a cathode electrode on the entire surface including the organic layer; and

making the cathode electrode in such a way as to have a film thickness that differs depending on the emission color. The same applies to other embodiments described later.

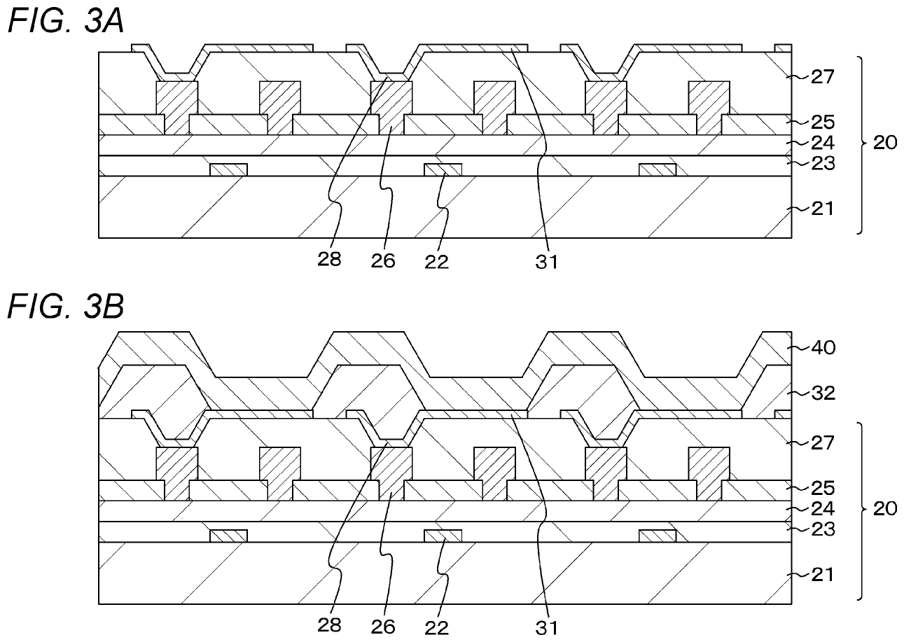

FIGS. 3 to 9 are schematic partial end views for explaining the method for manufacturing the display device according to the first embodiment.

The method for manufacturing the display device 1 will now be described in detail with reference to these drawings.

### [Step-100] (See FIG. 3A)

First, the circuit board 20 on which a drive circuit is formed is prepared. The base material 21 is prepared, and then the base material 21 is subjected to a predetermined film forming and patterning process, whereby the drive circuit including a thin film transistor is formed. Then, the planarization film 27 is formed on the entire surface of the drive circuit by a spin coating method, a slit coating method, a sputtering method, a CVD method, or the like. Next, after an opening is formed in the planarization film 27, the contact plug 28 is formed in the opening, and then the reflection film 31 is formed, whereby the circuit board 20 illustrated in FIG. 3A can be obtained.

### [Step-110] (See FIG. 3B)

Next, the partition 32 serving as an inter-pixel insulation film is formed between the reflection film 31 and the reflection film 31. An inorganic insulation film such as silicon oxynitride is formed on the entire surface including the reflection film 31 by a sputtering method, a CVD method, or the like. Subsequently, a pixel opening is patterned by a lithography method and a dry etching method so that the formed inorganic insulation film has a predetermined recess, whereby the partition 32 can be formed. Next, the organic layer 40 that emits white light is formed on the entire surface including the reflection film 31 by, for example, sequentially forming a hole injection layer, a hole transport layer, a red light emission layer, a light emission separation layer, a blue light emission layer, a green light emission layer, and an electron transport layer.

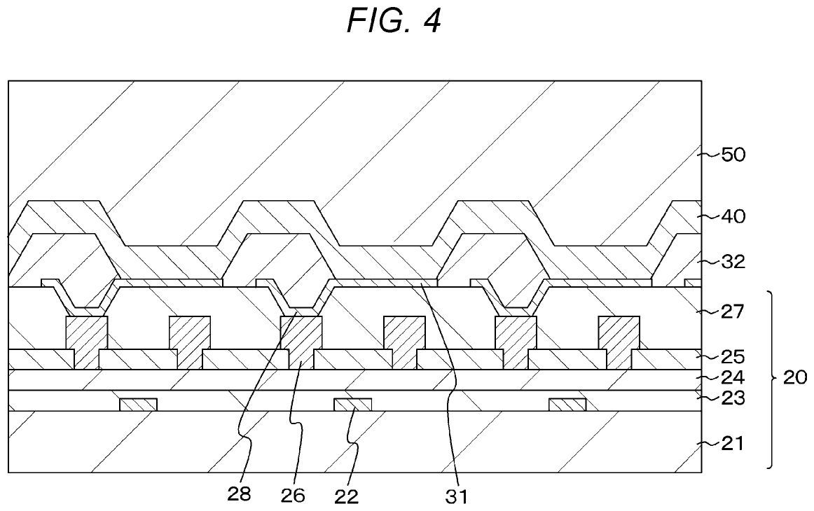

### [Step-120] (See FIG. 4)

Next, the cathode electrode 50 is formed on the entire surface of the organic layer 40. The cathode electrode 50 can be obtained by, for example, forming a film of indium zinc oxide (IZO) on the entire surface by a sputtering method.

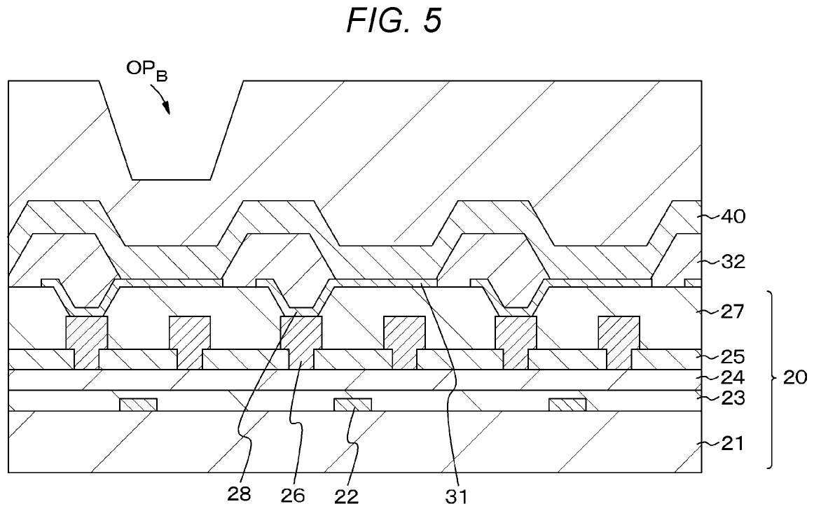

### [Step-130] (See FIGS. 5, 6, and 7)

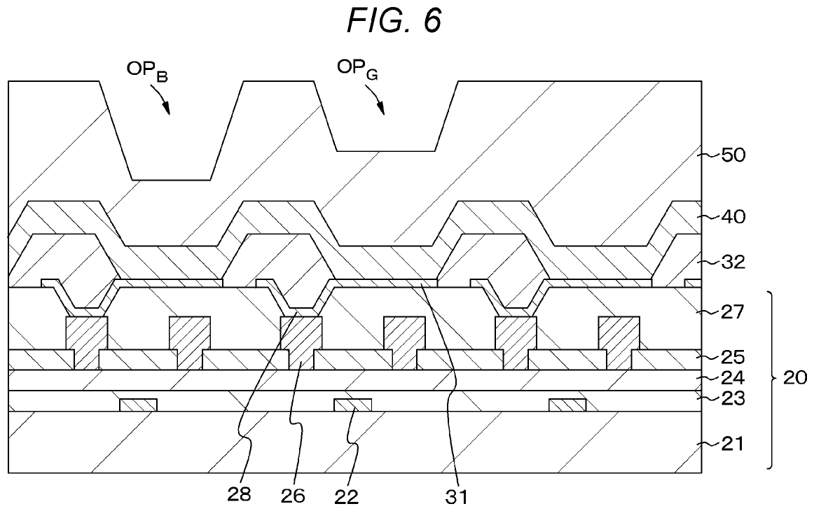

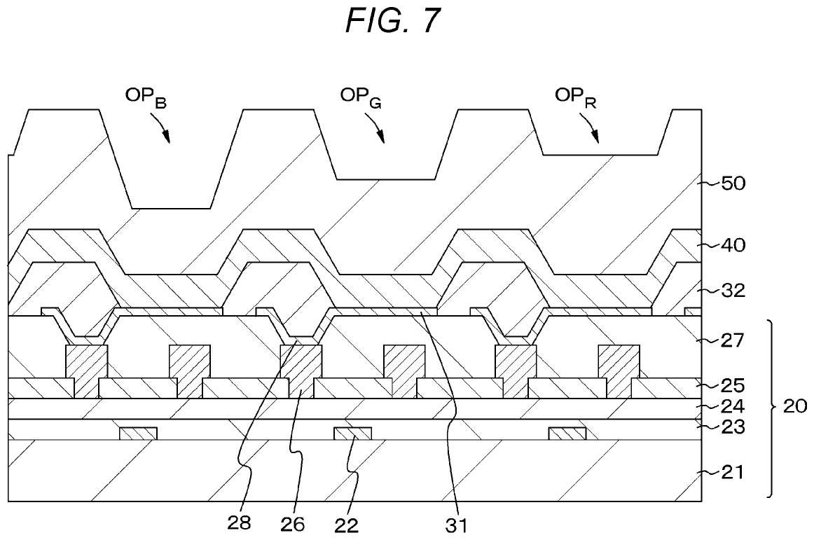

Next, the film thickness of the cathode electrode 50 is adjusted in accordance with the emission color. First, a mask having an opening corresponding to the pixel 10 whose emission color is blue is formed on the cathode electrode 50 and is dry-etched to form a recess OP_{B} in the cathode electrode 50 (see FIG. 5). Next, a mask having an opening corresponding to the pixel 10 whose emission color is green is formed on the cathode electrode 50 and is dry-etched to form a recess OP_{G} in the cathode electrode 50 (see FIG. 6). Then, a mask having an opening corresponding to the pixel 10 whose emission color is red is formed on the cathode electrode 50 and is dry-etched to form a recess OP_{R} in the cathode electrode 50 (see FIG. 7). The depth of the recess has a relationship of OP_{B}>OP_{G}>OP_{R}.

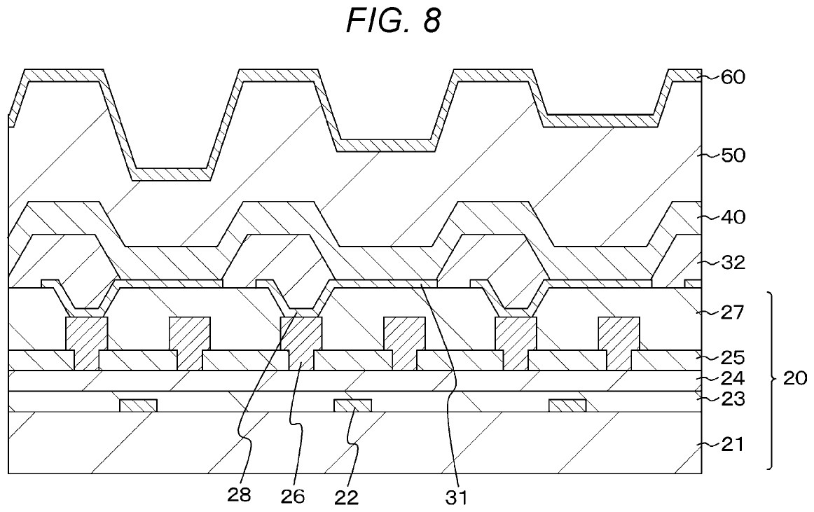

### [Step-140] (See FIG. 8)

Then, the semi-transmissive reflection film 60 is formed on the entire surface of the cathode electrode 50. The semi-transmissive reflection film 60 can be formed by using, for example, a vapor deposition method.

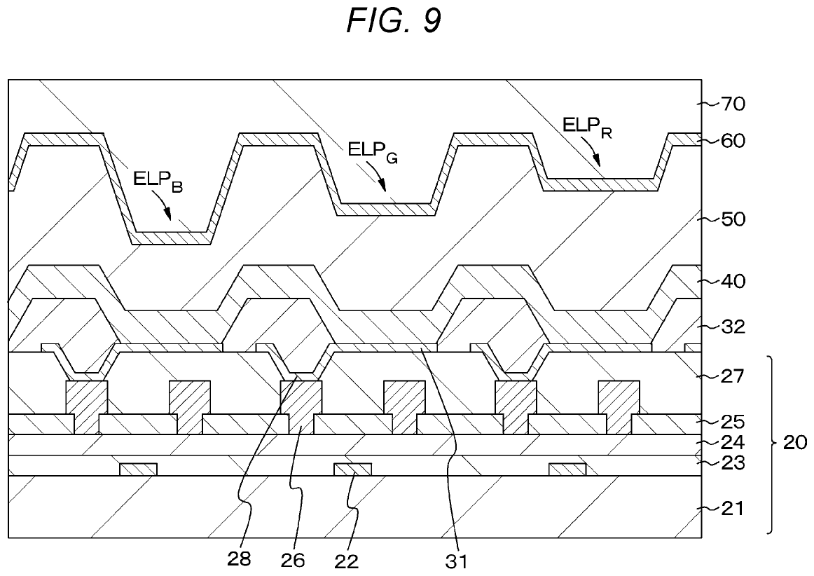

### [Step-150] (See FIG. 9)

Then, the protection film 70 is formed on the entire surface of the semi-transmissive reflection film 60 by using, for example, a CVD method. Then, a counter substrate or the like is stuck thereon as necessary. The display device 1 can be obtained through the steps described above.

As described above with reference to FIG. 2, a resonator structure is formed between the reflection film 31 and the semi-transmissive reflection film 60. The distance of this portion is defined by the thicknesses of the organic layer 40 and the cathode electrode 50. These thicknesses can be controlled with high precision due to the process of forming the components. Accordingly, the optical distance in the resonator structure can be set with high precision, and therefore, variations in luminous efficacy and emission color caused by variations in resonator structure can be suppressed.

In addition, the film thickness can be adjusted by providing a recess in the cathode electrode 50 that has been formed to be thick, eliminating the need for a film forming process of forming an optical path length adjustment layer into an extremely thin layer. Therefore, the present embodiment has an advantage of excellent manufacturability.

### Second Embodiment

The second embodiment is a modification of the first embodiment. A major difference from the first embodiment is that the cathode electrode is in a layered structure including layers of different compositions.

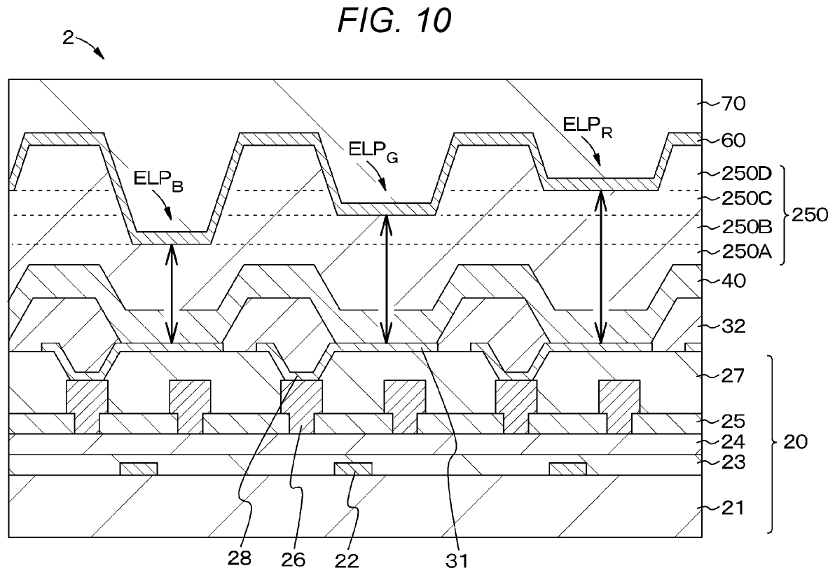

FIG. 10 is a schematic partial cross-sectional view of a display device according to a second embodiment. Note that a schematic plan view of the display device according to the second embodiment is found in FIG. 1 by replacing the display device 1 with the display device 2.

The display device 2 is different from the display device 1 in configuration of the cathode electrode 250.

The cathode electrode 250 includes four layers, namely a first layer 250A, a second layer 250B, a third layer 250C, and a fourth layer 250D, from the organic layer 40 side. These layers each include, for example, indium tin oxide (ITO), but are formed to have different selectivities to an etchant by applying different film forming conditions when the films are formed by a sputtering method or the like.

As in the first embodiment, the cathode electrode 250 is formed to be an electrode common to the individual pixels 10. In addition, a recess is disposed in a portion of the cathode electrode 250, the portion corresponding to the reflection film (anode electrode) 31. The depth of the recess differs depending on the emission color. More specifically, the recess corresponding to the pixel 10 for red emission color is formed such that the third layer 250C serves as a stopper layer, the recess corresponding to the pixel 10 for green emission color is formed such that the second layer 250B serves as a stopper layer, and the recess corresponding to the pixel 10 for blue emission color is formed such that the first layer 250A serves as a stopper layer.

The thickness of each layer included in the cathode electrode 250 is set such that the optical distance between the reflection film 31 and the semi-transmissive reflection film 60 is an optical distance in accordance with the display color of the pixel 10 by forming the recesses described above.

The foregoing has described a detailed structure of the display device 2. The above-described display device 2 can be manufactured as follows.

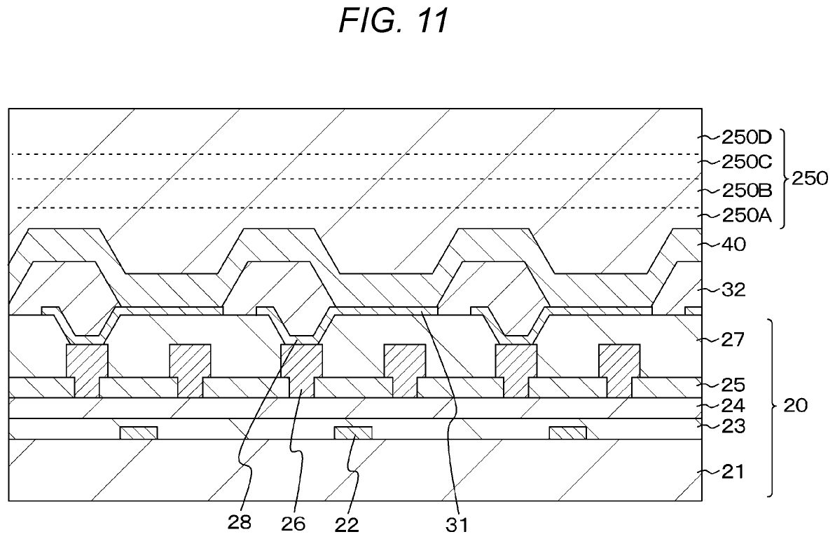

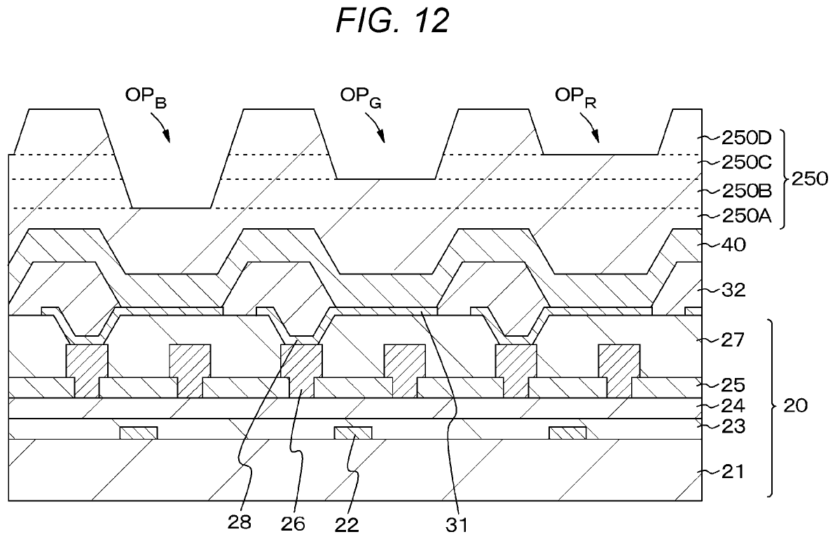

FIGS. 11 and 12 are schematic partial end views for explaining a method for manufacturing the display device according to the second embodiment.

### [Step-200]

First, the partition 32 and the organic layer 40 are formed on the circuit board 20 by performing steps similar to the steps described above in [Step-100] and [Step-110] (See FIG. 3B).

### [Step-210] (See FIG. 11)

Next, the cathode electrode 250 is formed on the entire surface of the organic layer 40. The cathode electrode 250 including the first layer 250A, the second layer 250B, the third layer 250C, and the fourth layer 250D is formed by, for example, stacking layers each including indium zinc oxide (IZO) by a sputtering method under different film forming conditions.

### [Step-220] (See FIG. 12)

Next, the film thickness of the cathode electrode 250 is adjusted in accordance with the emission color. First, a mask having an opening corresponding to the pixel 10 whose emission color is blue is formed on the cathode electrode 250 and is dry-etched to form a recess OP_{B} in the cathode electrode 250. Next, a mask having an opening corresponding to the pixel 10 whose emission color is green is formed on the cathode electrode 250 and is dry-etched to form a recess OP_{G} in the cathode electrode 250. Then, a mask having an opening corresponding to the pixel 10 whose emission color is red is formed on the cathode electrode 250 and is dry-etched to form a recess OP_{R} in the cathode electrode 50. The depth of the recess has a relationship of OP_{B}>OP_{G}>OP_{R}.

### [Step-230]

After that, steps similar to the steps described above in [Step-140] and [Step 150] are performed. The display device 2 can be obtained through the steps described above.

The distance between the reflection film 31 and the semi-transmissive reflection film 60 is defined by the thicknesses of the organic layer 40 and the individual layers included in the cathode electrode 250. These thicknesses can be controlled with high precision due to the process of forming the components. Accordingly, the optical distance in the resonator structure can be set with high precision, and therefore, variations in luminous efficacy and emission color caused by variations in resonator structure can be suppressed.

### Third Embodiment

The third embodiment is also a modification of the first embodiment. A major difference from the first embodiment is that the light emission layer is formed for each pixel and the light emission layer emits the light of a color corresponding to the emission color of the pixel.

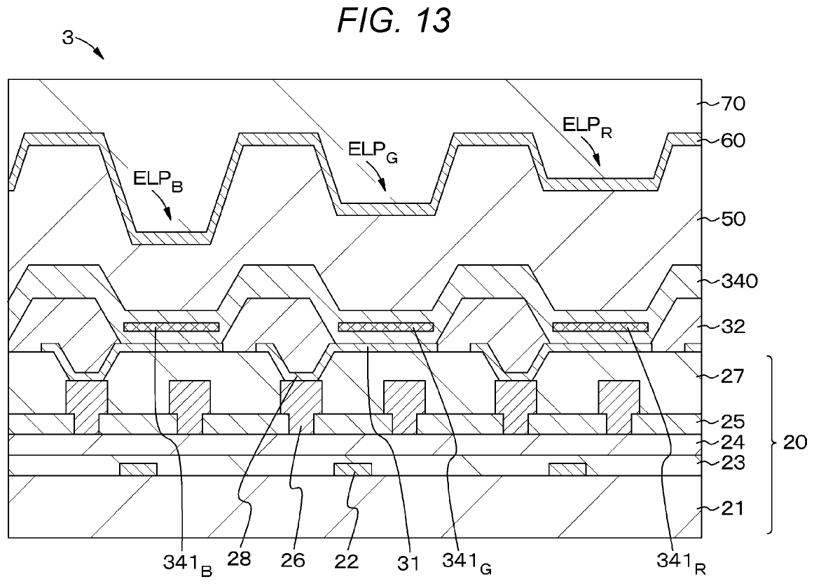

FIG. 13 is a schematic partial cross-sectional view of a display device according to a third embodiment. Note that a schematic plan view of the display device according to the third embodiment is found in FIG. 1 by replacing the display device 1 with the display device 3.

The organic layer 340 in the display device 3 also includes layers such as a hole injection layer, a hole transport layer, a red light emission layer, a blue light emission layer, a green light emission layer, and an electron transport layer, which include an organic material. The layers other than the light emission layers, such as the hole injection layer, the hole transport layer, and the electron transport layer, are disposed as a common continuous film on the entire surface including the reflection film, as in the first embodiment. On the other hand, the red light emission layer, the green light emission layer, and the blue light emission layer are formed for each pixel in accordance with the emission color of the pixel 10. In FIG. 13, the reference symbol 341_{R} denotes a red light emission layer, the reference symbol 341_{G} denotes a green light emission layer, and the reference symbol 341_{B} denotes a blue light emission layer.

According to this configuration, since the separate coating is only needed for the light emission layers while the other functional layers are common layers, alignment can be done relatively easily. Furthermore, since the light emission layer emits light of a color corresponding to the pixel 10, the present embodiment has an advantage that color purity and brightness can be improved.

The foregoing has described a detailed structure of the display device 3. The display device 3 described above can be manufactured by a method similar to the manufacturing method described in the first embodiment, except that the light emission layer is separately coated for each pixel.

### Fourth Embodiment

The fourth embodiment is also a modification of the first embodiment. A difference from the first embodiment is that formation of a recess can be omitted for some of the pixels.

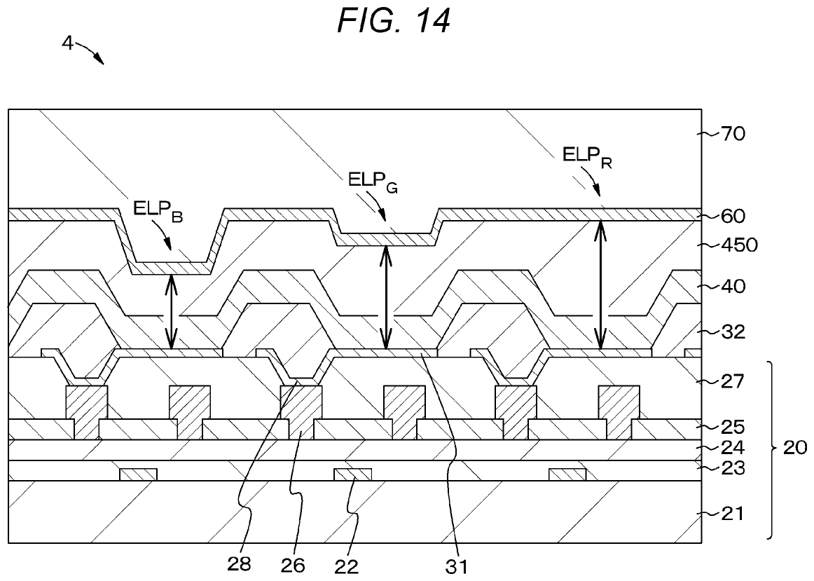

FIG. 14 is a schematic partial cross-sectional view of a display device according to a fourth embodiment. Note that a schematic plan view of the display device according to the fourth embodiment is found in FIG. 1 by replacing the display device 1 with the display device 4.

The cathode electrode 450 in the display device 4 is also formed to be an electrode common to the individual pixels 10. In addition, a recess is disposed in a portion of the cathode electrode 50, the portion corresponding to the reflection film (anode electrode) 31. However, unlike the first embodiment, the cathode electrode 450 is formed to have a thickness that allows a resonance state suitable for red to be obtained without forming a recess. Therefore, recesses are formed in the cathode electrode 450 corresponding to the pixel 10 for green display and the pixel 10 for blue display only.

The foregoing has described a detailed structure of the display device 4. The above-described display device 4 can be manufactured as follows.

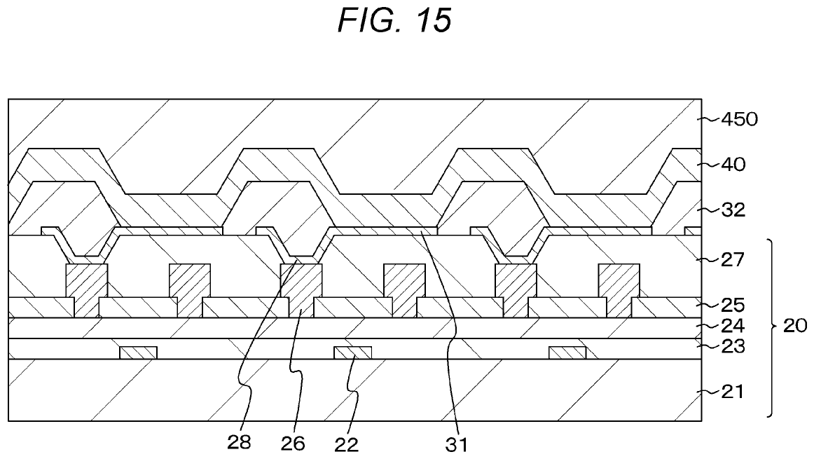

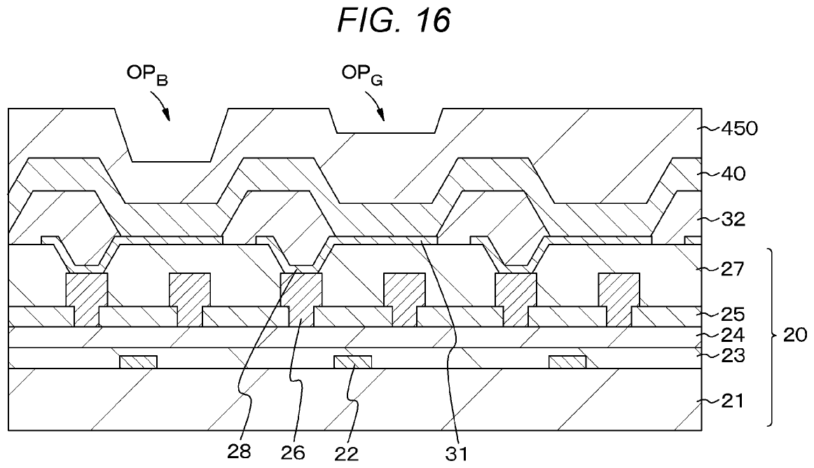

FIGS. 15 and 16 are schematic partial end views for explaining a method for manufacturing the display device according to the fourth embodiment.

### [Step-400]

First, the partition 32 and the organic layer 40 are formed on the circuit board 20 by performing steps similar to the steps described above in [Step-100] and [Step-110] (See FIG. 3B).

### [Step-410] (See FIG. 15)

Next, the cathode electrode 450 is formed on the entire surface of the organic layer 40. As described above, the cathode electrode 450 is formed to have a thickness that allows a resonance state suitable for red to be obtained.

### [Step-420] (See FIG. 16)

Next, the film thickness of the cathode electrode 450 is adjusted in accordance with the emission color. First, a mask having an opening corresponding to the pixel 10 whose emission color is blue is formed on the cathode electrode 450 and is dry-etched to form a recess OP_{B} in the cathode electrode 250. Next, a mask having an opening corresponding to the pixel 10 whose emission color is green is formed on the cathode electrode 450 and is dry-etched to form a recess OP_{G} in the cathode electrode 250.

### [Step-230]

After that, steps similar to the steps described above in [Step-140] and [Step 150] are performed. The display device 4 can be obtained through the steps described above.

In addition to the advantages described in the first embodiment, the fourth embodiment further has an advantage of reducing the processing steps for making the cathode electrode. Therefore, the present embodiment has an advantage of more excellent manufacturability.

In each of the various display devices according to the present disclosure described above, the organic layer and the transparent cathode electrode are stacked between the reflection film and the semi-transmissive reflection film, the organic layer including the light emission layer; the semi-transmissive reflection film is formed on the cathode electrode; and the cathode electrode is formed to have a film thickness that differs depending on the emission color. Thus, the optical distance in a resonator structure can be set with high precision by appropriately setting the film thickness of the cathode electrode.

### [Electronic Apparatus]

The display device of the present disclosure described above can be used as a display unit (display device) of an electronic apparatus in any field for displaying video signals input to the electronic apparatus or video signals generated in the electronic apparatus as an image or video. For example, the display device can be used as a display unit in a television set, a digital still camera, a notebook personal computer, a mobile terminal device such as a mobile phone, a video camera, a head-mounted display (a display attached on one's head), and so on.

The display device of the present disclosure may even include a module-shaped device in a sealed configuration. An example may be a display module formed by attaching opposed units including transparent glass or the like to the pixel array unit. Note that the display module may be provided with a circuit unit, a flexible printed circuit (FPC), and the like for inputting and outputting signals and the like from the outside to the pixel array unit. As specific examples of an electronic apparatus employing the display device of the present disclosure, a digital still camera and a head-mounted display are shown below. Note that, however, the specific examples illustrated here are not restrictive but are merely examples.

### Specific Example 1

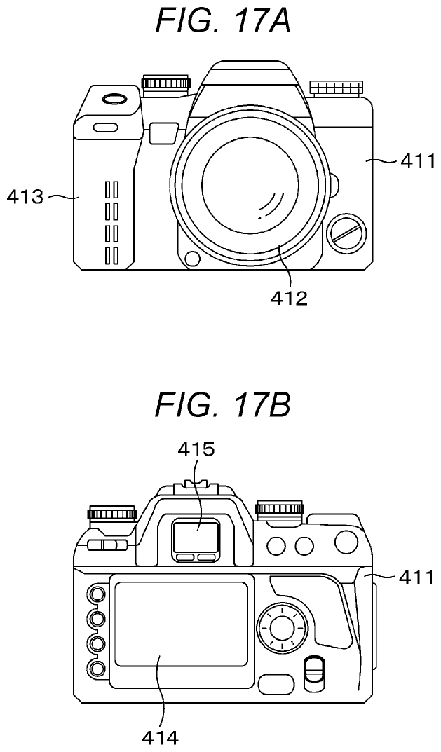

FIG. 17 is an external view of a lens-interchangeable single-lens reflex type digital still camera; FIG. 17A shows a front view thereof and FIG. 17B shows a rear view thereof. The lens-interchangeable single-lens reflex type digital still camera includes, for example, an interchangeable photographing lens unit (interchangeable lens) 412 on the front right side of a camera main body (camera body) 411 and a grip portion 413 to be gripped by a photographer on the front left side.

In addition, a monitor 414 is disposed substantially in the center of the rear surface of the camera main body 411. A viewfinder (eyepiece window) 415 is disposed above the monitor 414. By looking through the viewfinder 415, the photographer can visually recognize the optical image of the subject guided from the photographing lens unit 412 to determine the composition.

In the lens-interchangeable single-lens reflex type digital still camera as configured above, the display device of the present disclosure can be used as the viewfinder 415. That is, the lens-interchangeable single-lens reflex type digital still camera according to the present example is produced by using the display device of the present disclosure as the viewfinder 415.

### Specific Example 2

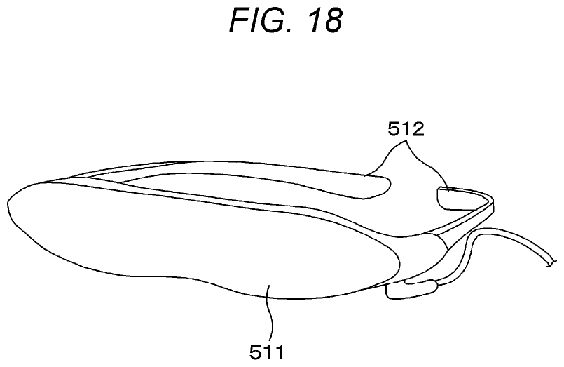

FIG. 18 is an external view of a head-mounted display. The head-mounted display includes, for example, an ear hook portion 512 on both sides of an eyeglass-shaped display portion 511 so that the head-mounted display is attached on the user's head. In the head-mounted display, the display device of the present disclosure can be used as the display portion 511. That is, the head-mounted display according to the present example is produced by using the display device of the present disclosure as the display portion 511.

### Specific Example 3

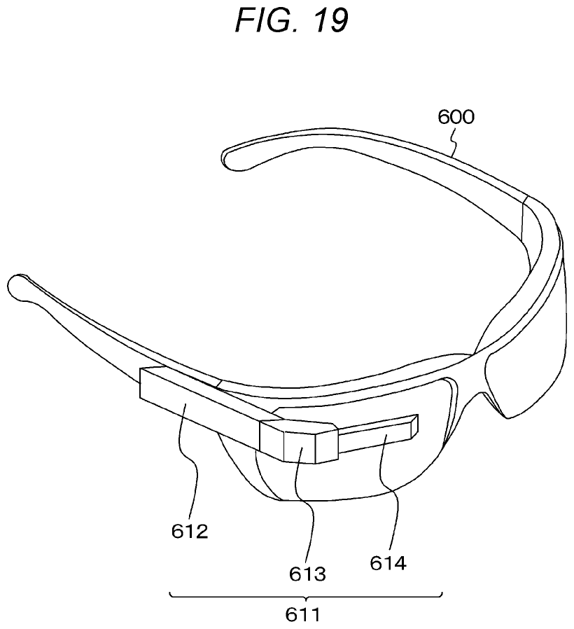

FIG. 19 is an external view of a see-through head-mounted display. The see-through head-mounted display 611 includes a main body 612, an arm 613, and a lens barrel 614.

The main body 612 is connected to the arm 613 and to eyeglasses 600. Specifically, an end of the main body 612 with respect to the long side direction is connected to the arm 613, and one of the side surfaces of the main body 612 is connected to the eyeglasses 600 via a connection member. Note that the main body 612 may be directly attached on the head of a human body.

The main body 612 contains a control board for controlling operations of the see-through head-mounted display 611 and also contains a display unit. The arm 613 connects the main body 612 and the lens barrel 614 and supports the lens barrel 614. Specifically, the arm 613 is coupled to an end of the main body 612 and to an end of the lens barrel 614 to fix the lens barrel 614. Furthermore, the arm 613 contains a signal line for exchanging data regarding an image provided by the main body 612 to the lens barrel 614.

The lens barrel 614 projects, through an eyepiece, the image light provided by the main body 612 via the arm 613 onto the eyes of the user wearing the see-through head-mounted display 611. In the see-through head-mounted display 611, the display device of the present disclosure can be used as the display unit in the main body 612.

### [Others]

Note that the technology of the present disclosure may have the following configurations.

### [A1]

A display device, in which

a reflection film and a semi-transmissive reflection film are disposed at a distance from each other, the distance differing depending on an emission color of a pixel,

an organic layer and a cathode electrode being transparent are stacked between the reflection film and the semi-transmissive reflection film, the organic layer including a light emission layer,

the semi-transmissive reflection film is formed on the cathode electrode, and

the cathode electrode is formed to have a film thickness that differs depending on the emission color.

### [A2]

The display device according to [A1], in which the reflection film has a function of an anode electrode.

### [A3]

The display device according to [A1] or [A2], in which

the cathode electrode includes indium zinc oxide (IZO).

### [A4]

The display device according to any one of [A1] to [A3], in which

the cathode electrode is formed as an electrode common to individual pixels, and

a recess is disposed in a portion of the cathode electrode, the portion corresponding to the reflection film.

### [A5]

The display device according to [A4], in which

a depth of the recess differs depending on the emission color.

### [A6]

The display device according to any one of [A1] to [A5], in which

an optical distance between the reflection film and the semi-transmissive reflection film is set to be an optical distance in accordance with a display color of the pixel, because of the cathode electrode being formed to have a film thickness that differs depending on the emission color.

### [A7]

The display device according to [A6], in which

the optical distance L satisfies a condition:

2L/λ+Φ/2π=m (m is an integer)

where symbol Φ represents a phase shift of reflected light generated in the semi-transmissive reflection film and the reflection film, symbol L represents the optical distance between the reflection film and the semi-transmissive reflection film, and symbol λ represents a peak wavelength of a spectrum of light taken from the pixel.

### [A8]

The display device according to any one of [A1] to [A7], in which

the semi-transmissive reflection film includes silver or an alloy including silver.

### [A9]

The display device according to any one of [A1] to [A8], in which

the light emission layer is formed in common throughout individual pixels.

### [A10]

The display device according to [A9], in which the light emission layer emits white light.

### [A11]

The display device according to any one of [A1] to [A8], in which

the light emission layer is formed for each pixel.

### [A12]

The display device according to [A11], in which

the light emission layer emits light of a color in accordance with the emission color of the pixel.

### [B1]

A method for manufacturing a display device, in which a reflection film and a semi-transmissive reflection film are disposed at a distance from each other, the distance differing depending on an emission color of a pixel, an organic layer and a cathode electrode being transparent are stacked between the reflection film and the semi-transmissive reflection film, the organic layer including a light emission layer, the semi-transmissive reflection film is formed on the cathode electrode, and the cathode electrode is formed to have a film thickness that differs depending on the emission color, the method including steps of:

forming the cathode electrode on an entire surface including the organic layer; and

making the cathode electrode in such a way as to have a film thickness that differs depending on the emission color.

### [B2]

The method for manufacturing the display device according to [B1], the method further including:

making the cathode electrode in such a way as to have a film thickness that differs depending on the emission color by forming a recess in a portion of the cathode electrode, the portion corresponding to the reflection film.

### [B3]

The method for manufacturing the display device according to [B1] or [B2], in which

the reflection film has a function of an anode electrode.

### [B4]

The method for manufacturing the display device according to any one of [B1] to [B4], in which

the cathode electrode includes indium zinc oxide (IZO).

### [B5]

The method for manufacturing the display device according to any one of [B1] to [B5], in which

the cathode electrode is formed as an electrode common to individual pixels, and

a recess is disposed in a portion of the cathode electrode, the portion corresponding to the reflection film.

### [B6]

The method for manufacturing the display device according to [B5], in which

a depth of the recess differs depending on the emission color.

### [B7]

The method for manufacturing the display device according to any one of [B1] to [B6], in which

an optical distance between the reflection film and the semi-transmissive reflection film is set to be an optical distance in accordance with a display color of the pixel, because of the cathode electrode being formed to have a film thickness that differs depending on the emission color.

### [B8]

The method for manufacturing the display device according to [B7], in which

the optical distance L satisfies a condition:

2L/λ+Φ/2π=m (m is an integer)

where symbol Φ represents a phase shift of reflected light generated in the semi-transmissive reflection film and the reflection film, symbol L represents the optical distance between the reflection film and the semi-transmissive reflection film, and symbol λ represents a peak wavelength of a spectrum of light taken from the pixel.

### [B9]

The method for manufacturing the display device according to any one of [B1] to [B8], in which

the semi-transmissive reflection film includes silver or an alloy including silver.

### [B10]

The method for manufacturing the display device according to any one of [B1] to [B9], in which

the light emission layer is formed in common throughout individual pixels.

### [B11]

The method for manufacturing the display device according to [B10], in which

the light emission layer emits white light.

### [B12]

The method for manufacturing the display device according to any one of [B1] to [B9], in which the light emission layer is formed for each pixel.

### [B13]

The method for manufacturing the display device according to [B12], in which

the light emission layer emits light of a color in accordance with the emission color of the pixel.

[C1]

An electronic apparatus including a display device, in which

a reflection film and a semi-transmissive reflection film are disposed at a distance from each other, the distance differing depending on an emission color of a pixel,

an organic layer and a cathode electrode being transparent are stacked between the reflection film and the semi-transmissive reflection film, the organic layer including a light emission layer,

the semi-transmissive reflection film is formed on the cathode electrode, and

the cathode electrode is formed to have a film thickness that differs depending on the emission color.

### [C2]

The electronic apparatus according to [C1], in which

the reflection film has a function of an anode electrode.

### [C3]

The electronic apparatus according to [C1] or [C2], in which

the cathode electrode includes indium zinc oxide (IZO).

### [C4]

The electronic apparatus according to any one of [C1] to [C3], in which

the cathode electrode is formed as an electrode common to individual pixels, and

a recess is disposed in a portion of the cathode electrode, the portion corresponding to the reflection film.

### [C5]

The electronic apparatus according to [C4], in which

a depth of the recess differs depending on the emission color.

### [C6]

The electronic apparatus according to any one of [C1] to [C5], in which

an optical distance between the reflection film and the semi-transmissive reflection film is set to be an optical distance in accordance with a display color of the pixel, because of the cathode electrode being formed to have a film thickness that differs depending on the emission color.

### [C7]

The electronic apparatus according to [C6], in which

the optical distance L satisfies a condition:

2L/λ+Φ/2π=m (m is an integer)

where symbol Φ represents a phase shift of reflected light generated in the semi-transmissive reflection film and the reflection film, symbol L represents the optical distance between the reflection film and the semi-transmissive reflection film, and symbol λ represents a peak wavelength of a spectrum of light taken from the pixel.

### [C8]

The electronic apparatus according to any one of [C1] to [C7], in which

the semi-transmissive reflection film includes silver or an alloy including silver.

### [C9]

The electronic apparatus according to any one of [C1] to [C8], in which

the light emission layer is formed in common throughout individual pixels.

### [C10]

The electronic apparatus according to [C9], in which

the light emission layer emits white light.

### [C11]

The electronic apparatus according to any one of [C1] to [C8], in which

the light emission layer is formed for each pixel.

### [C12]

The electronic apparatus according to [C11], in which

the light emission layer emits light of a color in accordance with the emission color of the pixel.

### REFERENCE SIGNS LIST

1, 2, 3, 4 Display device
10 Pixel
11 Display region
20 Circuit board
21 Base material
22 Gate electrode
23 Gate insulation film
24 Semiconductor material layer
25 Planarization film
26 Source/drain electrode
27 Planarization film
28 Contact plug
31 Reflection film (anode electrode)
32 Partition
40 Organic layer
341_{R} Red light emission layer
341_{G} Green light emission layer
341_{B} Blue light emission layer
50, 250, 450 Cathode electrode
250A First layer
250B Second layer
250C Third layer
250D Fourth layer
60 Semi-transmissive reflection film
70 Protection film
100 Power supply unit
101 Scanning unit
102 Data driver
411 Camera main body
412 Photographing lens unit
413 Grip portion
414 Monitor
415 Viewfinder
511 Eyeglass-shaped display portion
512 Ear hook portion
600 Eyeglasses (eyewear)
611 See-through head-mounted display
612 Main body
613 Arm
614 Lens barrel

1. A display device, wherein
a reflection film and a semi-transmissive reflection film are disposed at a distance from each other, the distance differing depending on an emission color of a pixel,
an organic layer and a cathode electrode being transparent are stacked between the reflection film and the semi-transmissive reflection film, the organic layer including a light emission layer,
the semi-transmissive reflection film is formed on the cathode electrode, and
the cathode electrode is formed to have a film thickness that differs depending on the emission color.

2. The display device according to claim 1, wherein
the reflection film has a function of an anode electrode.

3. The display device according to claim 1, wherein
the cathode electrode includes indium zinc oxide (IZO).

4. The display device according to claim 1, wherein
the cathode electrode is formed as an electrode common to individual pixels, and
a recess is disposed in a portion of the cathode electrode, the portion corresponding to the reflection film.

5. The display device according to claim 4, wherein
a depth of the recess differs depending on the emission color.

6. The display device according to claim 1, wherein
an optical distance between the reflection film and the semi-transmissive reflection film is set to be an optical distance in accordance with a display color of the pixel, because of the cathode electrode being formed to have a film thickness that differs depending on the emission color.

7. The display device according to claim 6, wherein
the optical distance L satisfies a condition:
2L/λ+Φ/2π=m (m is an integer)
where symbol Φ represents a phase shift of reflected light generated in the semi-transmissive reflection film and the reflection film, symbol L represents the optical distance between the reflection film and the semi-transmissive reflection film, and symbol λ represents a peak wavelength of a spectrum of light taken from the pixel.

8. The display device according to claim 1, wherein
the semi-transmissive reflection film includes silver or an alloy including silver.

9. The display device according to claim 1, wherein
the light emission layer is formed in common throughout individual pixels.

10. The display device according to claim 9, wherein
the light emission layer emits white light.

11. The display device according to claim 1, wherein
the light emission layer is formed for each pixel.

12. The display device according to claim 11, wherein
the light emission layer emits light of a color in accordance with the emission color of the pixel.

13. A method for manufacturing a display device, wherein a reflection film and a semi-transmissive reflection film are disposed at a distance from each other, the distance differing depending on an emission color of a pixel, an organic layer and a cathode electrode being transparent are stacked between the reflection film and the semi-transmissive reflection film, the organic layer including a light emission layer, the semi-transmissive reflection film is formed on the cathode electrode, and the cathode electrode is formed to have a film thickness that differs depending on the emission color, the method comprising steps of:
forming the cathode electrode on an entire surface including the organic layer; and
making the cathode electrode in such a way as to have a film thickness that differs depending on the emission color.

14. The method for manufacturing the display device according to claim 13, the method further comprising:
making the cathode electrode in such a way as to have a film thickness that differs depending on the emission color by forming a recess in a portion of the cathode electrode, the portion corresponding to the reflection film.

15. An electronic apparatus comprising a display device, wherein
a reflection film and a semi-transmissive reflection film are disposed at a distance from each other, the distance differing depending on an emission color of a pixel,
an organic layer and a cathode electrode being transparent are stacked between the reflection film and the semi-transmissive reflection film, the organic layer including a light emission layer,
the semi-transmissive reflection film is formed on the cathode electrode, and
the cathode electrode is formed to have a film thickness that differs depending on the emission color.
